(19) United States
(12) Patent Application Publication
(10) Pub. No.: US 2024/0117487 A1
(43) Pub. Date: Apr. 11, 2024

(54) 2D Layered Thin Film Structure

(71) Applicant: National Applied Research Laboratories, Taipei City (TW)

(72) Inventors: Shu-Ju Tsai, Tainan City (TW); Yi-Cheng Lin, Douliu City (TW)

(21) Appl. No.: 18/056,800

(22) Filed: Nov. 18, 2022

(30) Foreign Application Priority Data
Oct. 3, 2022 (TW) 111137596

(51) Int. Cl. C23C 16/26; C23C 16/48; C23C 16/513; H01L 21/02

(52) U.S. Cl. CPC C23C 16/26; C23C 16/48; C23C 16/513; H01L 21/02115; H01L 21/022; H01L 21/02274; H01L 21/0254; H01L 21/02568; H01L 21/02595; H01L 21/02598

(57) ABSTRACT

A 2D layered thin film structure is disclosed. The 2D layered thin film structure can be applied to the growth of monocrystalline or polycrystalline group III nitrides and other 2D materials. The 2D layered thin film structure can be easily separated from the 2D layered thin film structure growth substrate, so that a single or composite nanopillar array structure formed by the monocrystalline or polycrystalline group III nitride or other 2D materials, or the 2D layered thin film structure can be transferred to any other substrate. In addition, the 2D layered thin film structure has excellent light transmittance, flexibility and component integration.

### CROSS-REFERENCE TO RELATED APPLICATION

This application claims the benefit of Taiwan Patent Application No. 111137596, filed on Oct. 3, 2022, in the Taiwan Intellectual Property Office, the disclosure of which is incorporated herein in its entirety by reference.

### BACKGROUND OF THE INVENTION

### 1. Field of the Invention

The present invention generally relates to a 2D layered thin film structure, in particular to a 2D layered thin film structure made of grapheme which can shift the properties of n-type semiconductor material towards p-type semiconductor material.

### 2. Description of the Related Art

Grapheme is a flat film composed of carbon atoms in a hexagonal honeycomb lattice. It is a two-dimensional layered structure which has a two-dimensional structure and many excellent characteristics, for example, such as high carrier mobility, high mechanical strength and high thermal conductivity, etc., thus provides a wide range of applications, such as water purification films, DNA sequencing films, protective layers for organic light emitting diode (OLED) materials or filters for deep ultraviolet lithography applications, or as a conductor in electronic circuits and electro-optical devices.

There have been many methods for synthesizing grapheme, including mechanical exfoliation of graphite, epitaxial growth, silicon carbide (SiC) sublimation, chemical vapor deposition (deposition on catalytic metals such as copper, nickel, iron, etc.) and Chemical exfoliation (e.g., using graphite oxide to obtain grapheme oxide).

Among the above, although high-quality (low defect structure) single-layered grapheme can be obtained through the mechanical exfoliation of graphite and the epitaxial growth method, they still cannot provide grapheme films with a large area. On the other hand, although the silicon carbide sublimation method can provide grapheme films with a large area and a controllable number of layers, the silicon carbide substrate is too expensive; therefore, the above methods still have many limitations in practical application.

In addition, the more common chemical vapor deposition method uses a substrate with a catalytic metal layer (such as nickel or copper) to deposit a carbon source thereon to synthesize grapheme, although large-area and high-quality grapheme films can be obtained, due to the pretreatment temperature of 1000° C. for the synthesis of grapheme by chemical vapor deposition, the high temperature of nearly 1000 degrees and expensive metal substrates (such as copper or nickel) poses a limitation on manufacturing costs; while batch production in a horizontal furnace tube can achieve grapheme films with a large area, but commercial application is not possible since its discontinuous process is estimated to cost more than $100/inch.

Furthermore, the use of catalytic metals as substrates to generate grapheme is prone to problems such as residual contamination of metals (such as copper or nickel) and transposition support materials (such as polymethyl methacrylate, PMMA), and cracking and wrinkling of grapheme films during transposition process (refer to FIG. 1, which is a schematic view of point defects and folding of common commercially available grapheme) will affect the quality of the grapheme film.

In addition, in the grapheme film, the distance between grapheme layers is generally about 0.335 nm (refer to FIG. 2, which is a schematic view of a general distance between layers of grapheme), if the distance between layers can be reduced, it may improve the transmission efficiency of electrons and greatly enhance its application as a conductor, such as the preparation of flexible components, MicroLEDs, 3D integrated circuits (ICs), nanopillar components, and vertical two-dimensional material optoelectronic components.

As a result, in the practical application of grapheme films, it is still necessary to develop a grapheme film material with improved properties.

### SUMMARY OF THE INVENTION

In view of the above-mentioned problems of the conventional technology, the objective of the present disclosure is to overcome the shortcomings of the above-mentioned conventional technology. After years of research and experiments, the inventor(s) has finally developed a grapheme film having 2D layered thin film structure to effectively solve the problems of the conventional technology.

To achieve the foregoing objective, the present disclosure provides a grapheme film having 2D layered thin film structure, the grapheme film is formed by directly grow a grapheme having 2D layered thin film structure on various substrates that can withstand high temperatures in the process. The grapheme film having 2D layered thin film structure can be prepared without using catalytic metals such as copper or nickel as catalyst materials on the substrate. The grapheme film having 2D layered thin film structure prepared has the advantages of flat surface, good coverage and high purity, so that the grapheme film having 2D layered thin film structure or the single or composite nanopillar array structure material grown thereon can be easily transferred to any other substrate, which is beneficial for the application of grapheme thin-film materials in advanced research and development of emerging industries.

The preferred substrates that can withstand high temperatures in the process, for example, may be semiconductor wafers (including monocrystalline, polycrystalline or amorphous structures), insulating materials, compound semiconductor isomorphism and heterostructures, ceramics, glass, plastic polymers, composite materials, etc., but not limited thereto; in general, the thickness of the substrate used should be as thin as possible to ensure thermal uniformity across the substrate during the preparation of the grapheme film having 2D layered thin film structure, but the minimum thickness of the substrate is determined by the mechanical properties of the substrate and the maximum temperature it can withstand.

The semiconductor monocrystalline wafer material may be specifically silicon (Si), gallium arsenide (GaAs), indium phosphide (InP), gallium nitride (GaN), indium antimonate (InSb) or zinc oxide (ZnO).

The insulating material may be specifically silicon dioxide (SiO₂) or aluminum oxide (Al₂O₃).

The compound semiconductor isomorphism and heterostructure may be specifically indium phosphide (InP)/cadmium telluride (CdTe), gallium nitride (GaN)/indium gallium nitride (InGaN)/aluminum gallium nitride (AlGaN), silicon (Si)/aluminum nitride (AlN)/gallium nitride (GaN), gallium arsenide (GaAs)/aluminum indium gallium phosphide (AlInGaP), gallium nitride (GaN)/boron nitride (BN) or Silicon on Insulator (SOI).

The ceramic may be specifically zirconium dioxide, aluminosilicate, silicon nitride (Si₃N₄) or boron carbide (B₄C).

The glass may be specifically quartz, fused silica glass or borofluoride.

The plastic polymer may be specifically polyetherketone (PEK), polyetheretherketone (PEEK), polyamideimide (PAI) or polyphenylene sulfide (PPS).

The composite material may be specifically a fiber-reinforced polymer, a glass-reinforced matrix, or a carbon-containing composite material.

The single or composite nanopillar array structure material may be monocrystalline or polycrystalline group III nitrides, or other two-dimensional materials; the two-dimensional materials can be 2D allotropes, transition metal dichalcogenides (such as MoS₂, WS₂, ReS₂, PtSe₂, NbSe₂, etc.), Group V 2D materials (NbSe₂), main group metal chalcogenides (such as GaS, InSe, SnS, SnS₂, etc.), 2D oxides (such as MoO₃, V₂O₅) or their combination. Wherein chalcogenide is defined as a compound containing at least one chalcogen (an element other than oxygen in the oxygen group) ion and a less electronegative element; chalcogens generally refer to elements such as sulfur, selenium, tellurium, polonium, and helium, while elements with less electronegativity generally refer to arsenic, germanium, phosphorus, antimony, antimony, lead, boron, aluminum, gallium, gallium, indium, titanium and sodium (reference source: https://zh.m.wikipedia.org/zh-tw/ [symbol] ).

The 2D allotropes may be grapheme, phosphorene, germanene, silicone or borophene.

The grapheme film having 2D layered thin film structure may be prepared through the following method: using a Plasma-Enhanced Chemical Vapor Deposition system (PECVD system) to directly grow a 2D layered thin film structure on a substrate by a carbon-containing plasma to form the grapheme film.

Wherein, when growing the grapheme film having 2D layered thin film structure, the substrate is heated to 300˜800° C. first, electromagnetic waves are provided by a power supply to dissociate a methane gas (CH 4) in a reaction chamber of the Plasma-Enhanced Chemical Vapor Deposition system to generate the carbon-containing plasma, and deposit the carbon-containing plasma which is heated to 300˜800° C. on the substrate under 10⁻⁵˜200 torr pressure of the reaction chamber to form the grapheme film.

In addition, when the grapheme film having 2D layered thin film structure provided by the present disclosure contains oxygen as an impurity, the performance of the grapheme film can be improved.

Furthermore, in the grapheme film having 2D layered thin film structure prepared by the present disclosure, the distance between the layers of grapheme in the film is far lower than the distance between the layers of general commercially available grapheme, so the grapheme film provided by the present disclosure is denser between the layers than that of the general commercial grapheme films, and thus able to increase its applicability as a conductor.

Additionally, when the grapheme film having 2D layered thin film structure claimed by the present disclosure is applied to the growth of monocrystalline group III nitrides and transition metal dichalcogenides, whether growing or transposing monocrystalline or polycrystalline group III nitrides and transition metal dichalcogenides on the graphene film, or growing or transposing the graphene film on monocrystalline or polycrystalline group III nitrides and transition metal dichalcogenides, both may increase the work function of semiconductor materials such as monocrystalline or polycrystalline group III nitrides and transition metal dichalcogenides by more than 0.1 eV without the general doping process, so that semiconductor materials that is originally n-type may be shifted towards p-type semiconductor materials.

Therefore, the grapheme film having 2D layered thin film structure claimed by the present disclosure can significantly reduce the distance between the layers of grapheme in the grapheme film under a specific manufacturing process, and the prepared grapheme film having 2D layered thin film structure has the advantages of flat surface, good coverage and high purity, so that the materials grown on the grapheme film can be easily transferred to other substrates; in addition, when monocrystalline group III nitrides and transition metal dichalcogenides are grown on the grapheme thin film claimed by the present disclosure, the semiconductor materials with n-type characteristics can be shifted towards the semiconductor materials with p-type characteristics, so that the monocrystalline group III nitrides and transition metal dichalcogenides may have wider applicability.

Hereinafter, the technical features of the present disclosure, that is, the claimed grapheme film having 2D layered thin film structure, will be described through specific embodiments.

### BRIEF DESCRIPTION OF THE DRAWINGS

FIG. 1 is a schematic view showing the point defect and folding of common commercially available grapheme (reference source: https://www.graphenea.com/collections/buy-graphene-films/products/monolayer-graphene-on-sio-si-90-nm);

FIG. 2 is a schematic view showing the distance between layers of general grapheme (reference source: https://doi.org/10.1016/j.carbon.2013.01.032);

FIG. 3 is a schematic view of a two-inch grapheme thin film wafer prepared in an embodiment of the present disclosure;

FIG. 4 is a schematic view of a surface of the grapheme film according to an embodiment of the present disclosure observed under an optical microscope;

FIG. 5 is a schematic view showing the distance between layers of grapheme when sapphire is used as the growth substrate of the grapheme film according to an embodiment of the present disclosure;

FIG. 6(a) is a schematic view showing the resistance value of molybdenum disulfide decreases (gas response is negative) when molybdenum disulfide (n-type) is exposed to hydrogen sulfide gas; and FIG. 6(b) is a schematic view showing the case where the grapheme film according to an embodiment of the present disclosure is grown on molybdenum disulfide, since the work function of molybdenum disulfide lean towards p-type, the resistance value of molybdenum disulfide increases (gas response is positive) when exposed to hydrogen sulfide gas.

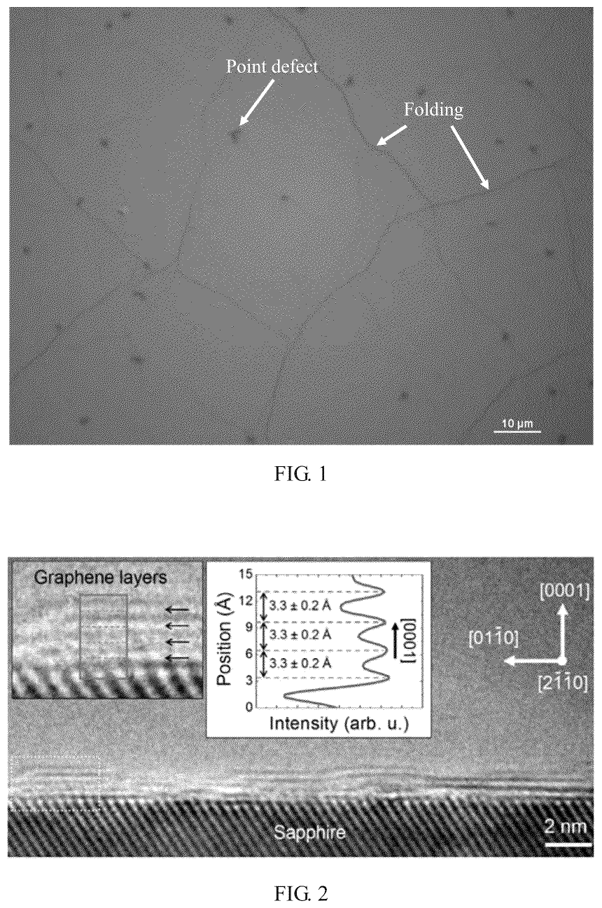

### DETAILED DESCRIPTION OF THE PREFERRED EMBODIMENTS

The technical content of the present disclosure will become apparent by the detailed description of the following embodiments and the illustration of related drawings as follows. The drawings are merely illustrative in nature and is in no way intended to limit the disclosure, its application, or uses. Therefore, while this disclosure may include particular ratio or configuration, the true scope of the disclosure should not be limited to such examples.

All terms (including technical and scientific terms) used herein have the meaning as commonly understood by one of ordinary skill in the art to which this disclosure belongs. It will be further understood that terms such as those defined in commonly used dictionaries should be construed as having meanings consistent with their meanings in the context of the related art and the present invention, and are not to be construed as idealized or excessively formal meaning unless expressly so defined herein.

All numerical values herein are understood to be modified by “about.” The term “about” as used herein intends to cover a variance of ±10%.

### Embodiment 1

The preparation of the grapheme film having 2D layered thin film structure Using a Plasma-Enhanced Chemical Vapor Deposition system (PECVD system) to directly grow a 2D layered thin film structure on a substrate by a carbon-containing plasma to form the grapheme film.

Wherein, when growing the grapheme film having 2D layered thin film structure, the substrate is heated to 300˜800° C. first, electromagnetic waves are provided by a power supply to dissociate a methane gas (CH₄) in a reaction chamber of the Plasma-Enhanced Chemical Vapor Deposition system to generate the carbon-containing plasma, and deposit the carbon-containing plasma which is heated to 300˜800° C. on the substrate under 10⁻⁵˜200 torr pressure of the reaction chamber to form the grapheme film.

Preferably, when growing the grapheme film having 2D layered thin film structure, the substrate temperature is first heated to 350˜750° C.; more preferably, when growing the grapheme film having 2D layered thin film structure, the substrate temperature is first heated to 400˜700° C.

Preferably, the pressure of the reaction chamber is 10⁻³˜200 torr; more preferably, the pressure of the reaction chamber is 10⁻²˜200 torr.

Preferably, when calculated in atomic percentage (At %), the oxygen content in the grapheme film is 5˜20 At %, and the carbon content in the grapheme film is 80˜95 At %; more preferably, the oxygen content in the grapheme film is 10˜18 At %, and the carbon content in the grapheme film is 82˜90 At %.

Preferably, the substrate may be monocrystalline, polycrystalline or amorphous gallium arsenide, zirconium dioxide, gallium nitride, silicon dioxide or aluminum oxide; more preferably, the substrate can be monocrystalline, polycrystalline or amorphous aluminum oxide.

Preferably, in the grapheme film, the distance between layers of grapheme is about 0.23˜0.29 nm; more preferably, the distance between layers of grapheme is about 0.23˜0.27 nm.

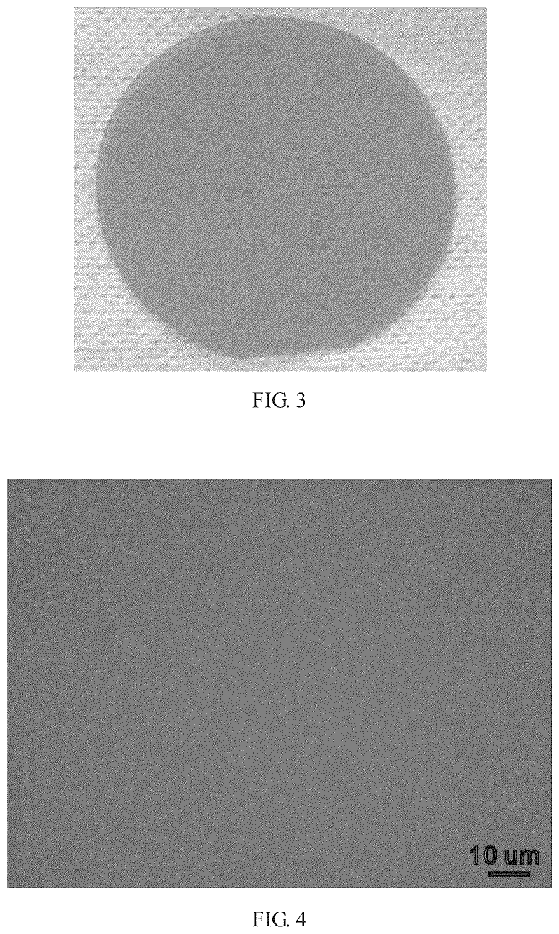

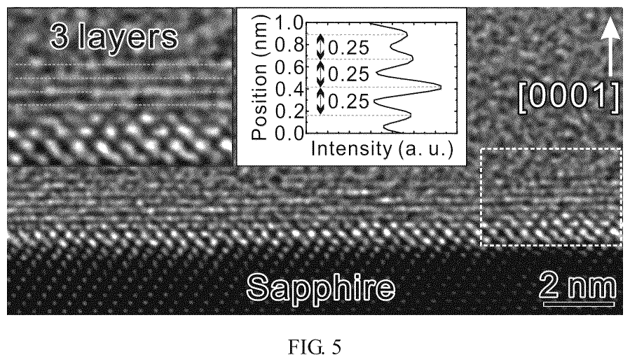

The two-inch grapheme film obtained under the above mentioned preparation conditions is as shown in FIG. 3, and it can be seen from FIG. 3 that the film is flat and has good coverage; observing the two-inch grapheme film with an optical microscope, it can be seen from FIG. 4 that compared with the general commercially available grapheme film, there is no obvious point defect and folding, and the purity is higher.

Referring to FIG. 5 again, it can be seen from FIG. 5 that the distance between each layer in the grapheme film is about 0.25±0.02 nm, thus the grapheme film can be made denser to increase its applicability as a conductor under the specific preparation method of the present disclosure.

### Embodiment 2

Semiconductor Material Characteristic Test

Monocrystalline or polycrystalline group III nitrides or transition metal dichalcogenides are deposited using methods such as Physical Vapor Deposition (PVD), Plasma-Assisted Molecular Beam Epitaxy (PA-MBE), Chemical Vapor Deposition (CVD), Plasma Enhanced Chemical Vapor Deposition (PECVD), Atomic Layer Deposition (ALD), Metal Organic Chemical Vapor Deposition (MOCVD), wet chemical or hydrothermal methods etc., to be grown on the grapheme film prepared by the present disclosure forming nanopillars, thin films or flakes, etc., for subsequent analysis of semiconductor material characteristics.

Preferably, the monocrystalline or polycrystalline group III nitride is gallium nitride (GaN), gallium aluminum (AlN), gallium indium (InN), and when the monocrystalline or polycrystalline group III nitride is grown on the grapheme film, it is preferably in the form of nanopillars or thin films; more preferably, the monocrystalline or polycrystalline group III nitride is gallium nitride (GaN).

Preferably, the transition metal dichalcogenide is molybdenum disulfide (MoS₂), tungsten disulfide (WS₂), and the transition metal dichalcogenide is preferably in the form of flakes or thin films when growing on the grapheme film; more preferably, the transition metal dichalcogenide is molybdenum disulfide (MoS₂).

Next, the single-crystal group III nitrides or transition metal dichalcogenides grown on the grapheme film prepared by the present disclosure were analyzed using the method described in the literature of Bitnuri Kwon (Bitnuri Kwon et al., Ultrasensitive N-Channel Graphene Gas Sensors by Nondestructive Molecular Doping, ACS Nano, 2022, 16, 2176-2187).

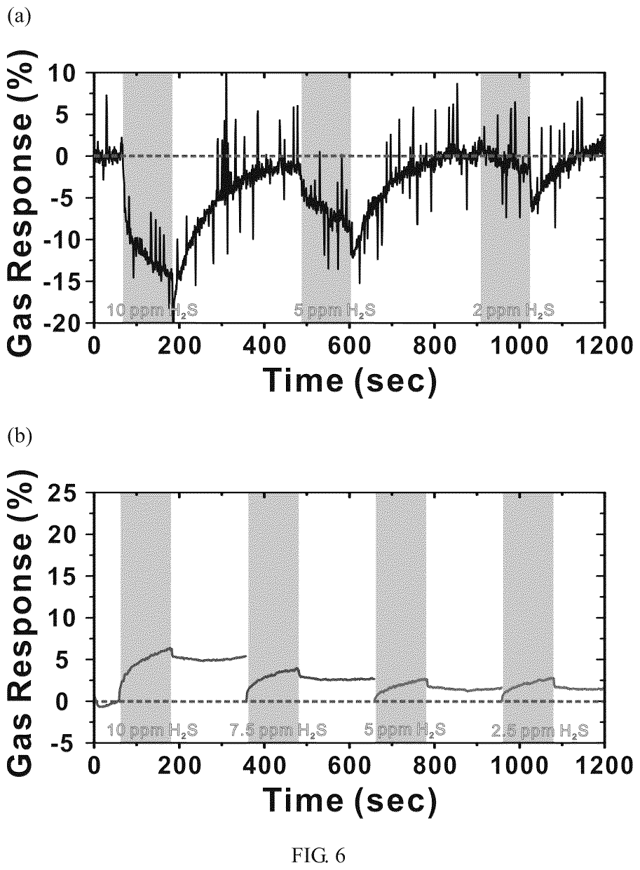

Referring to FIG. 6, wherein FIG. 6(a) is a schematic view showing the resistance value of molybdenum disulfide decreases (gas response is negative) when molybdenum disulfide (n-type) is exposed to hydrogen sulfide gas; and FIG. 6(b) is a schematic view showing the case where the grapheme film according to an embodiment of the present disclosure is grown on molybdenum disulfide, since the work function of molybdenum disulfide lean towards p-type, the resistance value of molybdenum disulfide increases (gas response is positive) when exposed to hydrogen sulfide gas. As can be seen from FIG. 6(a), since molybdenum disulfide is an n-type semiconductor, when exposed to hydrogen sulfide gas, hydrogen sulfide electrons are transferred to molybdenum disulfide. When the concentration of hydrogen sulfide is higher, more electrons are transferred to n-type molybdenum disulfide, which will make the resistance of molybdenum disulfide lower, which shows that the generally grown molybdenum disulfide is an n-type semiconductor; and as can be seen from FIG. 6(b), the higher the concentration of molybdenum disulfide in contact with hydrogen sulfide gas, the more obvious the increase in the resistance value of molybdenum disulfide, which means that molybdenum disulfide is transformed into a p-type semiconductor at this time, so when contacted with hydrogen sulfide gas, more electrons are transferred to molybdenum disulfide, which increases the resistance of p-type molybdenum disulfide, showing that after growing the grapheme film having 2D layered thin film structure of the present disclosure on molybdenum disulfide, the semiconductor properties of molybdenum disulfide can be transformed from n-type to p-type.

In summation of the description above, the grapheme film claimed by the present disclosure can significantly reduce the distance between layers of grapheme in the grapheme film under a specific process, and the grapheme film can be directly grown on the surface of the substrate that can withstand the process temperature, thus avoids the problem that it needs to be transferred to other substrates before use, and thus have the advantages of flat surface and high purity; in addition, when monocrystalline or polycrystalline group III nitrides and transition metal dichalcogenides are grown on the grapheme film having 2D layered thin film structure of the present disclosure, the semiconductor material with n-type characteristics can be shifted towards the semiconductor material with p-type characteristics, so that the application of monocrystalline or polycrystalline group III nitrides and transition metal dichalcogenides can be more extensive.

While the means of specific embodiments in present invention has been described by reference drawings, numerous modifications and variations could be made thereto by those skilled in the art without departing from the scope and spirit of the invention set forth in the claims. The modifications and variations should in a range limited by the specification of the present invention.

What is claimed is:

1. A grapheme film having 2D layered thin film structure, composed of carbon and oxygen, wherein
when calculated in atomic percentage (At %), the oxygen content in the grapheme film is 5˜20 At %, and the carbon content in the grapheme film is 80˜95 At %.

2. The grapheme film of claim 1, wherein a distance between layers in the grapheme film is 0.23˜0.29 nm.

3. The grapheme film of claim 2, wherein a method for preparation of the grapheme film is as follows:
using a Plasma-Enhanced Chemical Vapor Deposition system to directly grow a 2D layered thin film structure on a substrate by a carbon-containing plasma to form the grapheme film, wherein
the substrate is heated to 300˜800° C., electromagnetic waves are provided by a power supply to dissociate a methane gas in a reaction chamber of the Plasma-Enhanced Chemical Vapor Deposition system to generate the carbon-containing plasma, and deposit the carbon-containing plasma which is heated to 300˜800° C. on the substrate under 10⁻⁵˜200 torr pressure of the reaction chamber to form the grapheme film.

4. The grapheme film of claim 2, wherein properties of an n-type semiconductor material grown or transposed on the grapheme film are shifted towards p-type semiconductor material.

5. The grapheme film of claim 4, wherein the n-type semiconductor material is a monocrystalline or polycrystalline group III nitride or transition metal dichalcogenide.

6. The grapheme film of claim 4, wherein a work function of the n-type semiconductor material grown or transposed on the grapheme film is increased by at least 0.1 eV.

7. The grapheme film of claim 6, wherein the n-type semiconductor material is a monocrystalline or polycrystalline group III nitride or transition metal dichalcogenide.

8. The grapheme film of claim 2, wherein when the grapheme film is grown or transposed onto the n-type semiconductor material, properties of the n-type semiconductor material are shifted towards p-type semiconductor material.

9. The grapheme film of claim 8, wherein the n-type semiconductor material is a monocrystalline or polycrystalline group III nitride or transition metal dichalcogenide.

10. The grapheme film of claim 8, wherein when the grapheme film is grown or transposed onto the n-type semiconductor material, the work function of the n-type semiconductor material is increased by at least 0.1 eV.

11. The grapheme film of claim 10, wherein the n-type semiconductor material is a monocrystalline or polycrystalline group III nitride or transition metal dichalcogenide.

12. The grapheme film of claim 11, wherein the monocrystalline or polycrystalline group III nitride is gallium nitride, gallium aluminide or gallium indium.

13. The grapheme film of claim 11, wherein the transition metal dichalcogenide is molybdenum disulfide or tungsten disulfide.
